(19) United States
(12) Patent Application Publication
(10) Pub. No.: US 2015/0255356 A1
(43) Pub. Date: Sep. 10, 2015

(54) SUBSTRATE BAKING DEVICE AND TEMPERATURE ADJUSTING METHOD THEREOF

(71) Applicant: SHENZHEN CHINA STAR OPTOELECTRONICS TECHNOLOGY CO. LTD., Shenzhen, Guangdong (CN)

(72) Inventor: Jiangbo Yao, Shenzhen (CN)

(21) Appl. No.: 14/241,823

(22) PCT Filed: Jan. 21, 2014
(86) PCT No.: PCT/CN2014/070990

§ 371 Date: Jun. 3, 2014

(30) Foreign Application Priority Data
Dec. 31, 2013 (CN) 201310752239.X

(51) Int. Cl. H01L 21/66; H01L 21/68; H01L 21/67

(52) U.S. Cl. CPC H01L 22/26; H01L 21/67103; H01L 21/67253; H01L 21/68; H01L 22/12

(57) ABSTRACT

The present disclosure discloses a substrate baking device and a method for adjusting temperatures thereof. The substrate baking device comprises a baking device body having a hot plate composed of a plurality of subplates for baking a substrate, and a temperature adjusting mechanism for adjusting heating temperatures in the plurality of subplates of the baking device body. A heat conducting layer is arranged on the hot plate to cover the plurality of subplates. The substrate baking device is capable of improving film thickness uniformity.

### FIELD OF THE INVENTION

The present disclosure relates to the field of display technologies, in particular to a substrate baking device and a temperature adjusting method thereof.

### BACKGROUND OF THE INVENTION

In the half tone technique of four-photomask process for manufacturing TFT-LCDs (Thin Film Transistor Liquid Crystal Displays), photoresist residual film rates in various regions of a substrate after a photolithography process are subjected to strict requirements. In general, uniformity of the residual film rate after the photolithography process is required to reach 20% or below, even 10% or below in some cases. The term “residual film rate” refers to the residual film thickness of an unexposed portion after one or a plurality of procedures. In the prior art, the substrate needs to be exposed in a photolithography environment for about half an hour in general. And during the photolithography process, the substrate undergoes such procedures as cleaning, photoresist coating, vacuum drying, exposure, pre-baking, developing, post-baking, etc. Each of the above procedures is likely to lead to differences of the residual film rates in various areas of the substrate in practice.

### SUMMARY OF THE INVENTION

One technical problem to be solved by the present disclosure is to provide a substrate baking device capable of improving film thickness uniformity of a substrate.

To solve the above technical problem, the technical solution of the present disclosure is to provide a substrate baking device, which comprises a baking device body having a hot plate composed of a plurality of subplates for baking a substrate, and a temperature adjusting mechanism for adjusting heating temperatures of the plurality of subplates of the baking device body.

Compared with the prior art, the substrate baking device according to the present disclosure has the following advantages. The temperatures of the subplates can be adjusted through the temperature adjusting mechanism, thus achieving the purpose of adjusting film thicknesses of a plurality of regions of the substrate corresponding to the plurality of subplates. In this manner, film thickness uniformity of the plurality of areas of the substrate can be improved.

In one preferred embodiment, a heat conducting layer is arranged on the hot plate to cover the plurality of subplates. It can be understood that two adjacent subplates may differ greatly in the heating temperatures thereof, and poor film thickness uniformity at a joint area between the adjacent subplates could be easily generated if no transition for temperature is provided. The heat conducting layer as arranged can provide a more uniform heat conduction, especially for heat conduction at corners and joint areas of the subplates.

In one embodiment, the temperature adjusting mechanism includes: a film thickness monitoring unit for detecting film thicknesses of the plurality of regions of the substrate corresponding to the plurality of subplates; a data storage and calculating unit connected to the film thickness monitoring unit for receiving film thickness data transmitted by the film thickness monitoring unit and then calculating adjustment temperature values for the plurality of subplates; and a temperature adjusting unit connected to the data storage and calculating unit and the baking device body for receiving data transmitted by the data storage and calculating unit, and then adjusting the temperatures of the plurality of subplates accordingly.

The temperatures of the subplates can be adjusted according to actual conditions through film thickness detection and temperature compensation, thus improving the film thickness uniformity.

In one preferred embodiment, the plurality of subplates each include a plate body and a heating member arranged below the plate body, wherein all the heating members are connected to the temperature adjusting mechanism. Heating temperatures of the heating members corresponding to the plurality of the subplates respectively can be controlled through the temperature adjusting mechanism. Generally, the heating member is preferably in the form of a resistance wire or a heating wire. Such heating members are simple in structure, low in cost, and easy to be implemented.

In one preferred embodiment, the distance between the hot plate and the substrate can be adjusted. Better film thickness uniformity can be achieved by adjusting the distance between the hot plate and the substrate according to different situations.

In one preferred embodiment, the distance between the hot plate and the substrate ranges from 5 to 20 mm, which can ensure heating effects of the substrate by the plurality of subplates, and also ensure good film thickness uniformity.

Another technical problem to be solved by the present disclosure is to provide a method for adjusting the heating temperature of the substrate baking device, wherein the method is capable of improving the film thickness uniformity of the substrate by adjusting the heating temperatures of corresponding subplates according to the residual film thicknesses in the plurality of regions of the substrate.

To solve the above technical problem, a method for adjusting the heating temperature of the substrate baking device according to the present disclosure is provided, including the following steps: detecting, after a first photolithography process, residual film thicknesses of a plurality regions of the substrate through the temperature adjusting mechanism; calculating corresponding temperature compensation values according to the relationship between residual film thickness and temperature; and adjusting, through the temperature adjusting mechanism, the heating temperatures of the plurality of subplates of the baking device body according to the temperature compensation values.

According to the method, the residual film thickness of one substrate can be firstly measured before a plurality of substrates is to be detected. Then, the heating temperatures of the plurality of subplates of the baking device body can be adjusted, in order to improve the film thickness uniformity and yield for the plurality of substrates. And for a substrate that is subjected to a plurality of photolithography processes, according to the method, the heating temperatures can be adjusted after a first photolithography process among the plurality of photolithography processes is completed, thereby ensuring the final film thickness uniformity of the substrate.

As an improvement of the method of the present disclosure, the temperature adjusting mechanism includes a film thickness monitoring unit, a data storage and calculating unit, and a temperature adjusting unit. The film thickness monitoring unit detects the residual film thicknesses of the plurality regions of the substrate, and transmits the residual film thickness data to the data storage and calculating unit. The data storage and calculating unit compares the residual film thicknesses with a stored reference value, calculates temperature compensation values according to the relationship between the stored film thickness and temperature, and transmits the temperature compensation values to the temperature adjusting unit. The temperature adjusting unit adjusts the output powers of the plurality of subplates of the baking device body according to the corresponding temperature compensation values, thereby achieving the purpose of adjusting the temperatures of the plurality of subplates with easy operation.

According to the method of the present disclosure, a direct proportional relationship exists between the residual film thickness and the temperature, and also between the temperature and the power. A linear adjustment relationship can better facilitate adjustment of the film thickness uniformity.

As another improvement of the method of the present disclosure, the output power is lowered when the residual film thickness value is higher than the reference value, and raised when the residual film thickness value is lower than the reference value. Higher residual film thickness value means good baking effect, and the heating temperature can be lowered by reducing the output power in an appropriate way. Lower residual film thickness value means poor attachment stability of baking, and thus the temperature needs to be increased by raising the output power.

As a preferred embodiment of the method of the present disclosure, the adjusting method can be used in pre-baking and/or post-baking procedures in the photolithography process. The purpose of obtaining better film thickness uniformity can be achieved by adjusting the temperatures of pre-baking or post-baking in the photolithography process, or by simultaneously adjusting the temperature of the pre-baking procedure and that of the post-baking procedure in the photolithography process.

### BRIEF DESCRIPTION OF THE DRAWINGS

FIG. 1 is a schematic diagram of one specific example of a baking device body in a substrate baking device according to the present disclosure;

FIG. 2 is a schematic diagram of a hot plate in the baking device body as shown in FIGS. 1; and

FIG. 3 is a schematic diagram of one specific example of the substrate baking device according to the present disclosure.

### DETAILED DESCRIPTION OF THE EMBODIMENTS

The present disclosure will be further illustrated below in conjunction with the accompanying drawings and specific embodiments.

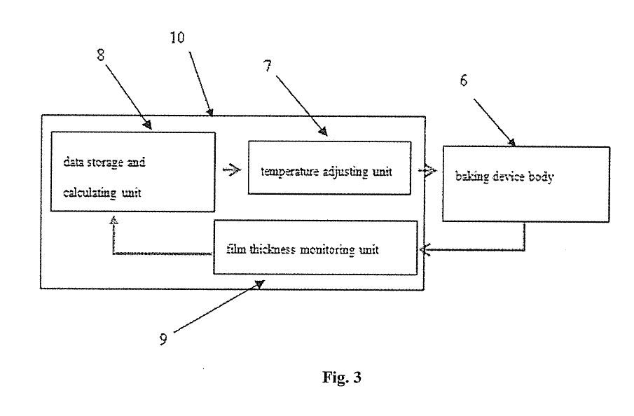

FIG. 3 shows a specific embodiment of a substrate baking device according to the present disclosure. In this embodiment, the substrate baking device includes a temperature adjusting mechanism 10, and a baking device body 6 for baking a substrate.

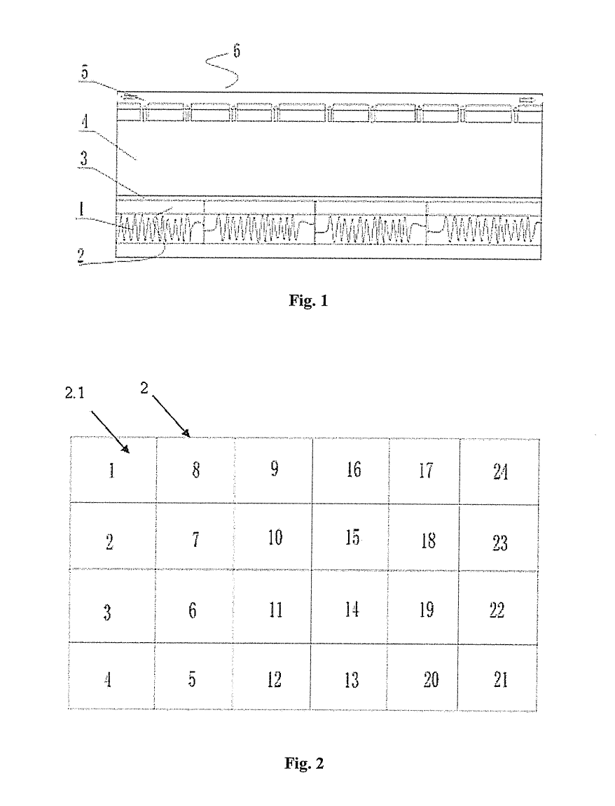

FIG. 1 shows a specific structure of the baking device body 6. The baking device body 6 includes a hot plate 2 (as shown in FIG. 2) composed of a plurality of subplates 2.1, wherein the plurality of subplates 2.1 each include a plate body and a heating member 1 arranged below the plate body. The heating member 1 is generally made of a resistance wire or a heating wire, the heating temperature of which can be adjusted through the temperature adjusting mechanism 10.

In addition, the baking device body 6 further includes a heat conducting layer 3 arranged on the hot plate 2. The heat conducting layer 3 covers the plurality of subplates 2.1, and is preferably in the form of a heat conducting copper plate.

Moreover, the baking device body 6 further includes a substrate chamber 4, which is in the form of a cavity arranged in the baking device body 6 and between the heat conducting layer 3 and a top cover. The substrate chamber 4 is placed on the heat conducting layer 3 and has a substrate disposed therein, so that the substrate, in non-direct contact with the heat conducting layer 3, is generally supported by supporting pins. Therefore, the heat conduction between the heat conducting layer 3 and the substrate is mainly accomplished through air conduction.

Besides, the baking device body 6 further includes a ventilation member 5, including a plurality of vent holes arranged on the top cover of the substrate chamber 4 and a ventilation channel communicated with the vent holes. The ventilation member 5 is used for heat dissipation of the substrate chamber 4.

In a preferred embodiment, the distance between the hot plate 2 and the substrate, or between the heat conducting layer 3 and the substrate, can be adjusted when the substrate is being mounted. The distance between the hot plate 2 and the substrate can be adjusted through supporting pins having adjustable lengths or the like. Preferably, the distance between the hot plate 2 and the substrate is in the range from 5 to 20 mm after the substrate is mounted.

As shown in FIG. 3, the temperature adjusting mechanism 10 includes a film thickness monitoring unit 9 for detecting the film thicknesses of a plurality of regions of the substrate corresponding to the plurality of subplates 2.1; a data storage and calculating unit 8 connected to the film thickness monitoring unit 9 for receiving film thickness data transmitted by the film thickness monitoring unit 9 and then calculating adjustment temperature values for the plurality of subplates 2.1; and a temperature adjusting unit 7 connected to the data storage and calculating unit 8 and the baking device body 6 for receiving data transmitted by the data storage and calculating unit 8 and then adjusting the temperatures of the plurality of subplates 2.1 accordingly.

The present disclosure further discloses a method for adjusting heating temperature of the substrate baking device. In a first embodiment, the temperature adjusting mechanism includes a film thickness detection sensor, and a controller containing a calculating unit, and the method includes the following steps: detecting residual film thicknesses of the plurality of regions through the film thickness detection sensor after a first photolithography process for a substrate; and transmitting the residual film thicknesses detected to the controller, which calculates corresponding temperature compensation values according to the relationship between residual film thickness and temperature, and then adjusts the heating temperatures of the plurality of subplates 2.1 by adjusting the current of the heating members 1 (e.g. resistance wires).

In a second embodiment, as shown in FIG. 3, the temperature adjusting mechanism 10 includes a film thickness monitoring unit 9, a data storage and calculating unit 8, and a temperature adjusting unit 7. The film thickness monitoring unit 9 detects the residual film thicknesses of the plurality of regions of the substrate, and transmits the residual film thickness data to the data storage and calculating unit 8. The data storage and calculating unit 8 compares the residual film thicknesses with a stored reference value, calculates temperature compensation values according to the relationship between the stored film thickness and temperature, and transmits the temperature compensation values to the temperature adjusting unit 7. The temperature adjusting unit 7 then correspondingly adjusts the output powers of the plurality of subplates 2.1 of the baking device body 6 according to the temperature compensation values.

In the first and second embodiments, there is a proportional relationship between the residual film thickness and the temperature, and between the temperature and the power.

In the second embodiment, the output power is lowered when the residual film thickness value is higher than the reference value, and raised when the residual film thickness value is lower than the reference value. The effect of improving film thickness uniformity can be achieved by adjusting the output power.

The method for adjusting the heating temperature of the substrate baking device according to the present disclosure can be used independently in a pre-baking procedure or a post-baking procedure in the photolithography process. Alternately, the adjusting method can be used simultaneously in the pre-baking procedure and the post-baking procedure for respectively adjusting the heating temperature of the baking device body 6 in the pre-baking procedure and the heating temperature of the baking device body 6 in the post-baking procedure.

The substrate baking device and the temperature adjusting method thereof according to the present disclosure can improve the residual film rate uniformity of a half tone layer after a photolithography process, reduce the problem of mura in dry etch resulted from non-uniform film thicknesses, and that of heterogeneous electric properties caused by inconsistent thicknesses and lengths of conducting wires on the substrate, and thus improve the display performance of TFT-LCD.

Although the present disclosure has been described in conjunction with the preferred embodiments, it can be understood that various modifications or substitutes could be made to the present disclosure without departing from the scope of the present disclosure. Particularly, all features in all the embodiments may be combined together as long as structural conflicts do not exist, and the combined features to be formed are still within the scope of the present disclosure. The present disclosure is not limited to the specific embodiments disclosed herein, but encompasses all the technical solutions falling into the scope of the claims.

1. A substrate baking device, comprising:
a baking device body having a hot plate composed of a plurality of subplates for baking a substrate, and
a temperature adjusting mechanism for adjusting heating temperatures of the plurality of subplates of the baking device body.

2. The substrate baking device according to claim 1, wherein a heat conducting layer is arranged on the hot plate to cover the plurality of subplates.

3. The substrate baking device according to claim 1, wherein the temperature adjusting mechanism includes:
a film thickness monitoring unit for detecting film thicknesses of a plurality of regions of the substrate corresponding to the plurality of subplates,
a data storage and calculating unit connected to the film thickness monitoring unit for receiving film thickness data transmitted by the film thickness monitoring unit and then calculating adjustment temperature values for the plurality of subplates, and
a temperature adjusting unit connected to the data storage and calculating unit and the baking device body for receiving data transmitted by the data storage and calculating unit, and then adjusting the temperatures of the plurality of subplates accordingly.

4. The substrate baking device according to claim 1, wherein the plurality of subplates each include a plate body and a heating member arranged below the plate body, all the heating members being connected to the temperature adjusting mechanism.

5. The substrate baking device according to claim 1, wherein the distance between the hot plate and the substrate can be adjusted.

6. The substrate baking device according to claim 5, wherein the distance between the hot plate and the substrate ranges from 5 to 20 mm.

7. A method for adjusting a temperature of a substrate baking device,
the substrate baking device comprising a baking device body having a hot plate composed of a plurality of subplates for baking a substrate, and a temperature adjusting mechanism for adjusting heating temperatures of the plurality of subplates of the baking device body, and
the method comprising the following steps:
detecting, after a first photolithography process, residual film thicknesses in a plurality of regions of the substrate through the temperature adjusting mechanism;
calculating corresponding temperature compensation values according to the relationship between residual film thickness and temperature; and
adjusting, through the temperature adjusting mechanism, the heating temperatures of the plurality of subplates of the baking device body according to the temperature compensation values.

8. The method according to claim 7, wherein the temperature adjusting mechanism includes a film thickness monitoring unit, a data storage and calculating unit, and a temperature adjusting unit,
the film thickness monitoring unit detects the residual film thicknesses of the plurality of regions of the substrate, and transmits the residual film thickness data detected to the data storage and calculating unit;
the data storage and calculating unit compares the residual film thicknesses with a stored reference value, calculates temperature compensation values according to the relationship between the stored film thickness and temperature, and transmits the temperature compensation values to the temperature adjusting unit; and
the temperature adjusting unit adjusts output powers of the plurality of subplates of the baking device body according to the corresponding temperature compensation values.

9. The method according to claim 8, wherein a proportional relationship exists between the residual film thickness and the temperature, and between the temperature and the power.

10. The method according to claim 8, wherein further comprising the following steps:
lowering the output power when the residual film thickness value is higher than the reference value, and
raising the output power when the residual film thickness value is lower than the reference value.

11. The method according to claim 9, wherein further comprising the following steps:
lowering the output power when the residual film thickness value is higher than the reference value, and
raising the output power when the residual film thickness value is lower than the reference value.

12. The method according to claim 7, wherein the method is used in a pre-baking procedure and/or a post-baking procedure in the photolithography process.

13. A method for adjusting heating temperatures of the substrate baking device,
the substrate baking device comprising a baking device body having a hot plate composed of a plurality of subplates for baking the substrate, and a temperature adjusting mechanism for adjusting the heating temperatures in the plurality of subplates of the baking device body, a heat conducting layer being arranged on the hot plate to cover the plurality of subplates,
the method comprising the following steps:
detecting, after a first photolithography process, residual film thicknesses in a plurality of regions of the substrate through the temperature adjusting mechanism;
calculating corresponding temperature compensation values according to the relationship between residual film thickness and temperature; and
adjusting, through the temperature adjusting mechanism, the heating temperatures of the plurality of subplates of the baking device body according to the temperature compensation values.

14. The method according to claim 13, wherein the temperature adjusting mechanism includes a film thickness monitoring unit, a data storage and calculating unit, and a temperature adjusting unit,
the film thickness monitoring unit detects the residual film thicknesses of the plurality of regions of the substrate, and transmits the residual film thickness data detected to the data storage and calculating unit;
the data storage and calculating unit compares the residual film thicknesses with a stored reference value, calculates temperature compensation values according to the relationship between the stored film thickness and temperature, and transmits the temperature compensation values to the temperature adjusting unit; and
the temperature adjusting unit adjusts output powers of the plurality of subplates of the baking device body according to the corresponding temperature compensation values.

15. The method according to claim 14, wherein a proportional relationship exists between the residual film thickness and the temperature, and between the temperature and the power.

16. The method according to claim 14, wherein further comprising the following steps:
lowering the output power when the residual film thickness value is higher than the reference value, and
raising the output power when the residual film thickness value is lower than the reference value.

17. The method according to claim 15, wherein further comprising the following steps:
lowering the output power when the residual film thickness value is higher than the reference value, and
raising the output power when the residual film thickness value is lower than the reference value.

18. The method according to claim 13, wherein the method is used in a pre-baking procedure and/or a post-baking procedure in the photolithography process.
